(19) United States
(12) Patent Application Publication
(10) Pub. No.: US 2018/0215922 A1
(43) Pub. Date: Aug. 2, 2018

(54) COMPOUND, RESIST COMPOSITION FOR COLOR FILTER, COLOR FILTER, DYED FIBER, AND DYEING METHOD

(71) Applicant: CANON KABUSHIKI KAISHA, Tokyo (JP)

(72) Inventors: Hajime Muta, Zama-shi (JP); Yuko Katsumoto, Yokohama-shi (JP); Koromo Shirota, Kawasaki-shi (JP); Taichi Shintou, Saitama-shi (JP); Tsuyoshi Santo, Yokohama-shi (JP)

(21) Appl. No.: 15/868,022

(22) Filed: Jan. 11, 2018

(30) Foreign Application Priority Data
Jan. 31, 2017 (JP) 2017-016181

(51) Int. Cl. C09B 55/00; G03F 7/00; D06P 1/13

(52) U.S. Cl. CPC C09B 55/009; D10B 2331/02; D06P 1/13; G03F 7/0007

(57) ABSTRACT

An object is to provide a compound having high color developability and excellent heat resistance, and a resist composition for a color filter and a color filter that contain the dye composition. Another object is to provide a dyed polyamide fiber product having excellent wet rubbing fastness. The objects are achieved by a compound represented by the following general formula (1):

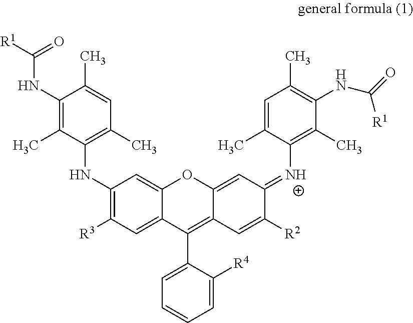

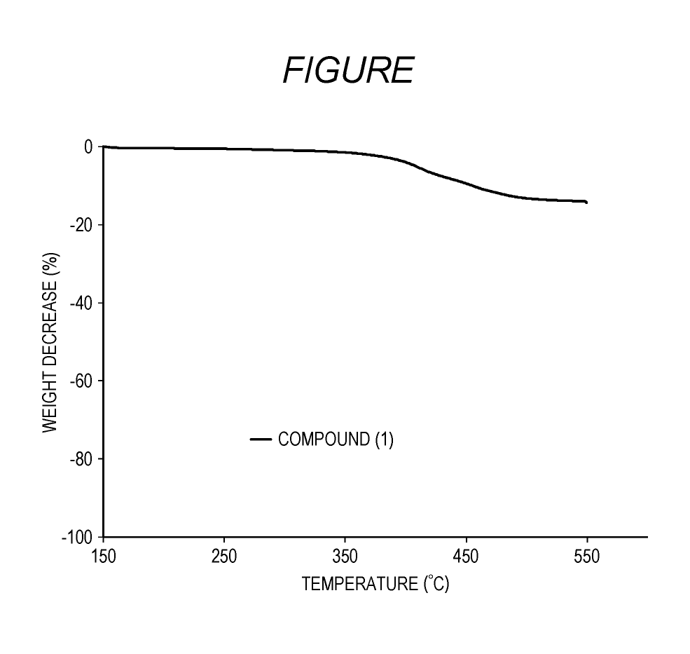

### BACKGROUND OF THE INVENTION

### Field of the Invention

The present invention relates to a compound, a resist composition for a color filter, a color filter, and a dyed fiber.

### Description of the Related Art

Displays using a light emitting device such as a liquid crystal, an organic electroluminescence (organic EL), and a light emitting diode (LED) are widely used in fields such as portable terminals typified by smart phones and tablet terminals, television receivers and digital signage systems. In recent years, high definition displays with typically 4K or 8K resolution have become widely used, so that color filters for use in the displays also are required to achieve improved performance corresponding to the high definition.

The size of picture elements is reduced in high definition displays, so that the aperture ratio of the picture elements is lowered. Consequently, the light intensity of light emitting devices is required to be increased in order to obtain bright and clear color development. In order to increase the light intensity of light emitting devices, dyes excellent in color development such as C.I. Acid Red 52 (AR52) and C.I. Acid Red 289 (AR289) are used (Japanese Patent No. 4911256 and Japanese Patent Application Laid-Open No. 2016-38463). Meanwhile, a dye with improvement on AR289 to achieve better light resistance is disclosed (Japanese Patent Application Laid-Open No. 2016-108545).

Due to the excellent color developability, AR289 is also used in dyeing silk scarfs and the like. Due to the poor wet rubbing fastness thereof, however, the wearability in a sweating state is restricted. Chemicals that enhance the bonding between a fiber and the dye have been therefore investigated.

### SUMMARY OF THE INVENTION

Color filters for use in smart phones or high-definition displays having 4K or 8K resolution tend to be exposed to increased heat generated from a light emitting device due to the enhanced light intensity of the light emitting device. AR289 and AR52 that are conventionally used have good color developability but poor in heat resistance. A compound having excellent heat resistance, therefore, needs to be developed.

Also, a dye for dyeing fiber having color developability equivalent to that of AR289, and excellent wet rubbing fastness, needs to be developed.

An object of the present invention is to provide a dye compound having high color developability and excellent heat resistance. Another object of the present invention is to provide a resist composition for a color filter and a color filter, with use of the dye composition.

A further another object of the present invention is to provide a dye and a dyed product having high color developability and excellent wet rubbing fastness.

The problem described above can be solved by using a compound represented by the following general formula (1).

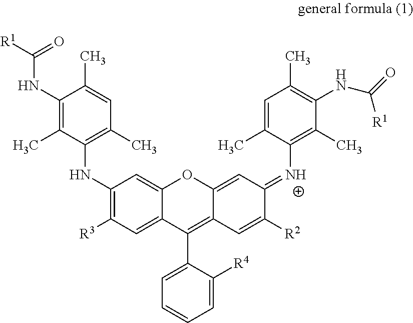

In the general formula (1), R¹ represents a straight-chain or branched alkyl group having 5 carbon atoms, R² represents a hydrogen atom, a sulfo group, a sulfonate group, a sulfonato group, or a sulfonamide group, and R³ and R⁴ each independently represent a sulfo group, a sulfonate group, a sulfonato group, or a sulfonamide group, wherein at least one of R² to R⁴ is a sulfonate ion. According to the present invention, a resist composition for a color filter having high color developability and excellent heat resistance can be obtained.

Further, according to the present invention, a color filter having excellent color development performance and heat resistance can be obtained.

Furthermore, according to the present invention, a polyamide-containing dyed fiber having high color developability and excellent wet rubbing fastness can be obtained.

According to the present invention, a compound having high color developability and excellent heat resistance can be provided. Further, according to the present invention, a resist composition for a color filter and a color filter having high color developability and excellent heat resistance can be provided. Furthermore, according to the present invention, a polyamide-containing dyed fiber having high color developability and excellent wet rubbing fastness can be obtained.

Further features of the present invention will become apparent from the following description of exemplary embodiments with reference to the attached drawing.

### BRIEF DESCRIPTION OF THE DRAWINGS

FIGURE is a chart illustrating thermal gravity/differential thermal analysis (TG-DTA) data on a compound (1) of the present invention.

### DESCRIPTION OF THE EMBODIMENTS

Preferred embodiments of the present invention will now be described in detail in accordance with the accompanying drawings.

The present invention is described in detail as follows, though the present invention is not limited thereto.

As a result of extensive study to solve the problem, the present inventors have found that using a compound represented by the following general formula (1), high color developability and excellent heat resistance can be achieved. The present inventors have further found that excellent wet rubbing fastness can be also achieved.

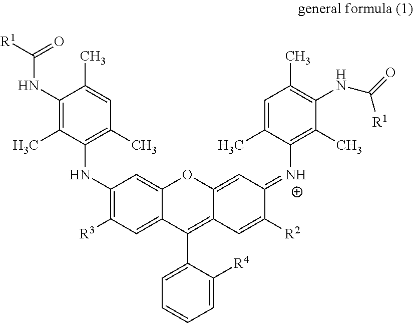

in the general formula (1), R¹ each independently represent a straight-chain or branched alkyl group having 5 carbon atoms, R² represents a hydrogen atom, a sulfo group, a sulfonate group, a sulfonato group, or a sulfonamide group, and R³ and R⁴ each independently represent a sulfo group, a sulfonate group, a sulfonato group, or a sulfonamide group, wherein at least one of R² to R⁴ is a sulfonato group.

The reason why the compound represented by the general formula (1) achieves improved heat resistance is presumably that the introduction of a sulfo group (—SO₃H), a sulfonate group, a sulfonato group (—SO₃⁻), or a sulfonamide group (−SO₂NR_{A}R_{B}; wherein R_{A} and R_{B} each represent a hydrogen atom or an alkyl group) at the 2-position or 7-position of a xanthene ring forms a hydrogen bond, which enhances the stacking effect between molecules.

Compounds represented by the general formula (1) with a total number of a sulfo group, a sulfonate group, a sulfonato group and a sulfonamide group of 1 as a whole have low solubility in water or organic solvents, being inclined to have lowered color developability similar to a pigment. In contrast, compounds represented by the general formula (1) with a total number of a sulfonic acid group, a salt of a sulfonic acid group, a sulfonate ion and a sulfonamide group of 4 or more as a whole have high water solubility and poor solubility in organic solvents, being inclined to have lowered heat resistance.

Also, with R¹ in the general formula (1) having 4 or less carbon atoms, the heat resistance is lowered due to reduction in affinity to a resin, while with R¹ having 6 or more carbon atoms, the heat resistance is lowered due to enhanced thermal mobility resulting from the increased flexibility of the R¹ molecular structure.

Examples of the alkyl group represented by R¹ in the general formula (1) include a straight-chain or branched alkyl group having 5 carbon atoms, though not particularly limited thereto. Specific examples thereof include an n-pentyl group, a (1-methyl)butyl group, a (2-methyl)butyl group, a (3-methyl)butyl group, a (1-ethyl)propyl group, a (1,1-dimethyl)propyl group, a (1,2-dimethyl)propyl group and a (2,2-dimethyl)propyl group. In particular, an n-pentyl group and a (2,2-dimethyl)propyl group are more preferred due to high color developability and excellent heat resistance.

The sulfonate group represented by R² to R⁴ in the general formula (1) is not particularly limited, and specific examples thereof include lithium sulfonate, sodium sulfonate and potassium sulfonate. In particular, sodium sulfonate is preferred due to high color developability and excellent heat resistance.

The sulfonamide group represented by R² to R⁴ in the general formula (1) is not particularly limited, and specific examples thereof include a sulfonamide group, an N-methylsulfonamide group, an N,N-dimethylsulfonamide group, an N-ethylsulfonamide group, an N,N-diethylsulfonamide group, an N-propylsulfonamide group, an N,N-dipropylsulfonamide group, an N-butylsulfonamide group, an N,N-dibutylsulfonamide group, an N-pentylsulfonamide group, an N,N-dipentylsulfonamide group, an N-hexylsulfonamide group, an N,N-dihexylsulfonamide group, an N-octylsulfonamide group, an N,N-dioctylsulfonamide group, an N-(2-ethylhexyl)sulfonamide group, an N,N-bis(2-ethylhexyl)sulfonamide group, an N-(1-methylhexyl)sulfonamide group, an N-(1-methylheptyl)sulfonamide group, an N-methyl-N-butylsulfonamide group, an N-methyl-N-pentylsulfonamide group, an N-methyl-N-hexylsulfonamide group, an N-methyl-N-octylsulfonamide group, an N-phenylsulfonamide group, an N-(p-methylphenyl) sulfonamide group, an N-pyrrolidylsulfonyl group and an N-piperidylsulfonyl group. In particular, an N-octylsulfonamide group, an N-(2-ethylhexyl)sulfonamide group and an N-piperidylsulfonyl group are more preferred due to high color developability and excellent heat resistance.

In the general formula (1), R² to R⁴ are more preferably a sulfo group, a sulfonato group or a sulfonamide group due to having high color developability and excellent heat resistance. In particular, R² and R³ can be a sulfo group or a sulfonamide group, and R⁴ can be a sulfonato group.

The compound represented by the general formula (1) includes tautomers represented by general formulas (2) and (3). In addition, with R⁴ being a sulfonic acid group, a salt of a sulfonic acid group or a sulfonate ion, an isomer represented by a general formula (4) is also present. All of the tautomers represented by the general formulas (2) to (4) are included in the scope of the present invention.

The R¹ to R⁴ in the general formulas (2) and (3) are the same as the R¹ to R⁴ in the general formula (1). Also, the R¹ to R³ in the general formula (4) are the same as the R¹ to R³ in the general formula (1).

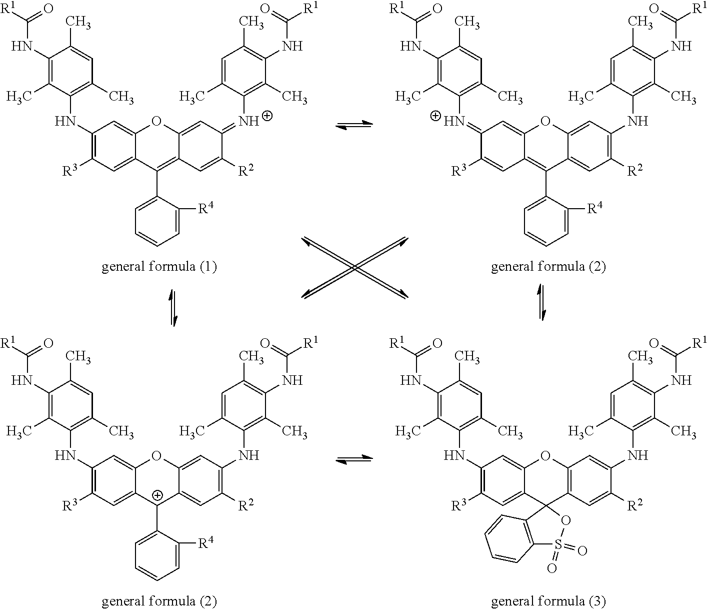

A compound having the structure represented by the general formula (1) can be synthesized with reference to known methods described in Japanese Patent No. 5451556, Japanese Patent Application Laid-Open No. 2016-108545, etc.

The compound represented by the general formula (1) of the present invention can be any compound shown in the following (1) to (56), though the present invention is not limited thereto.

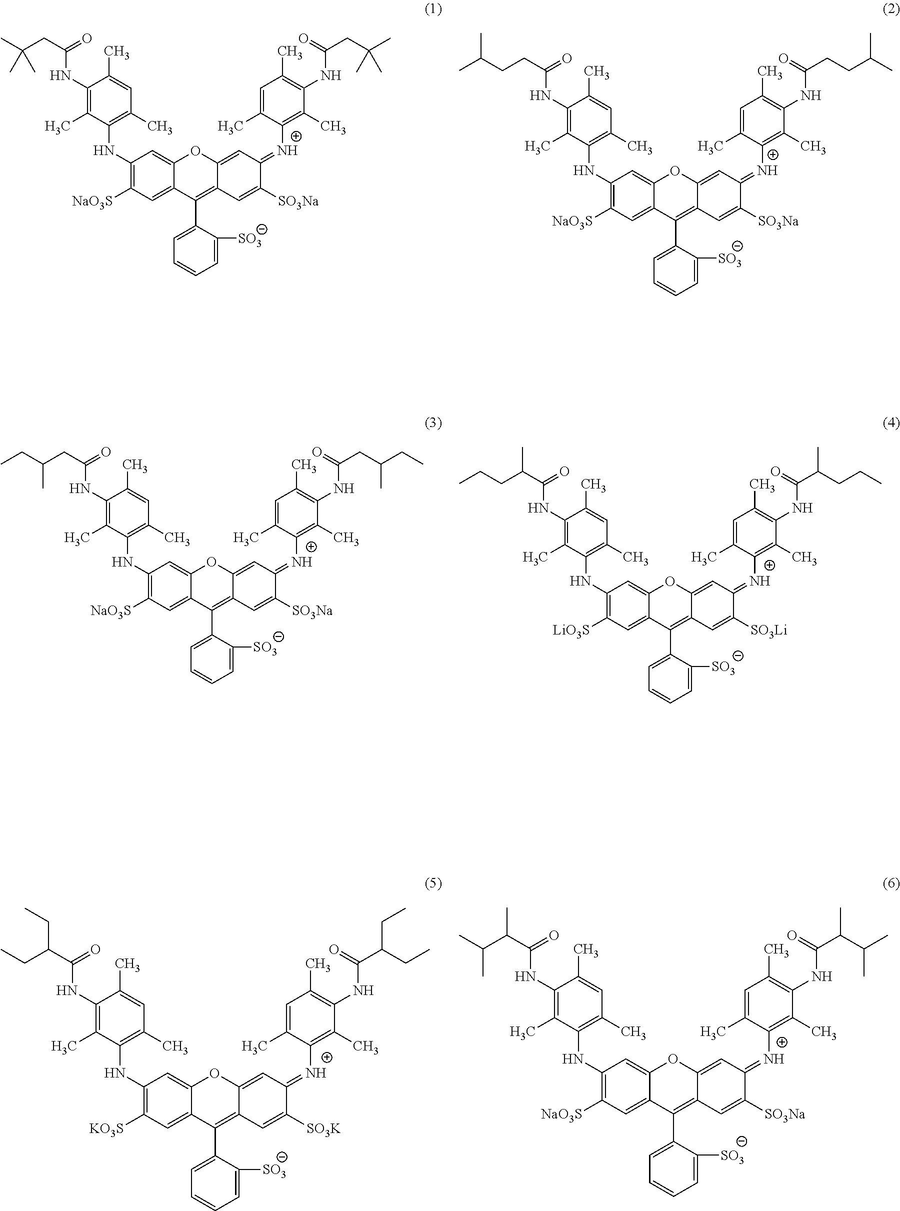

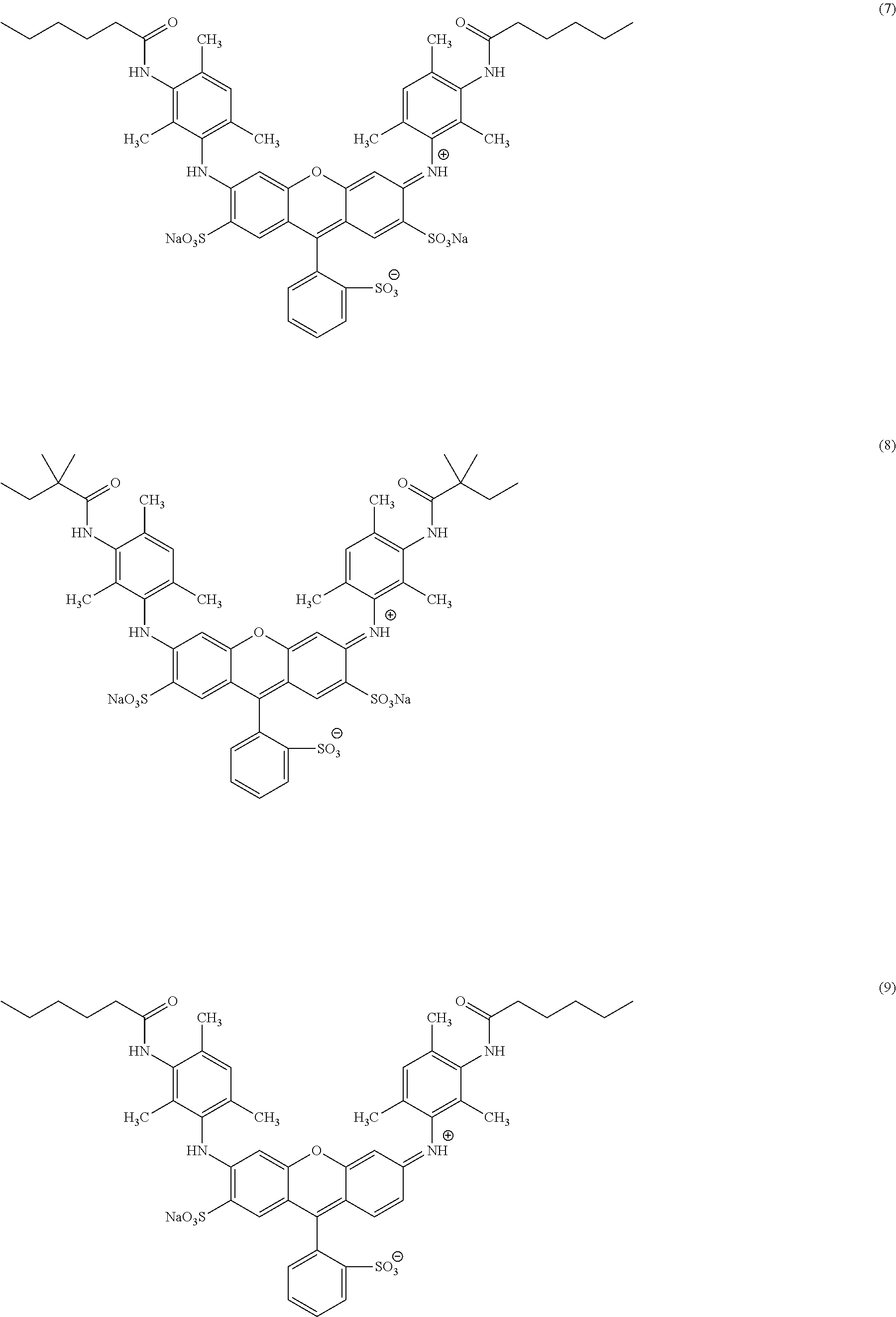

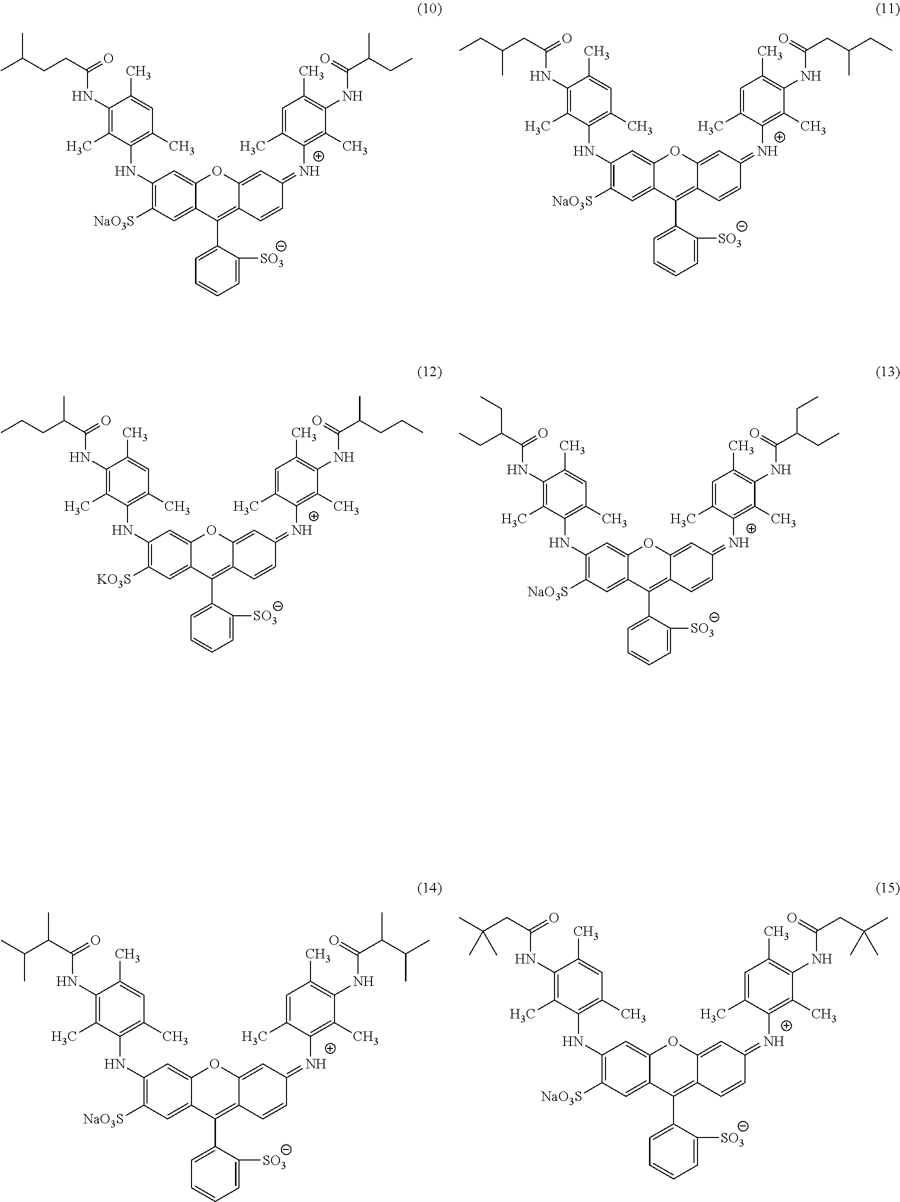

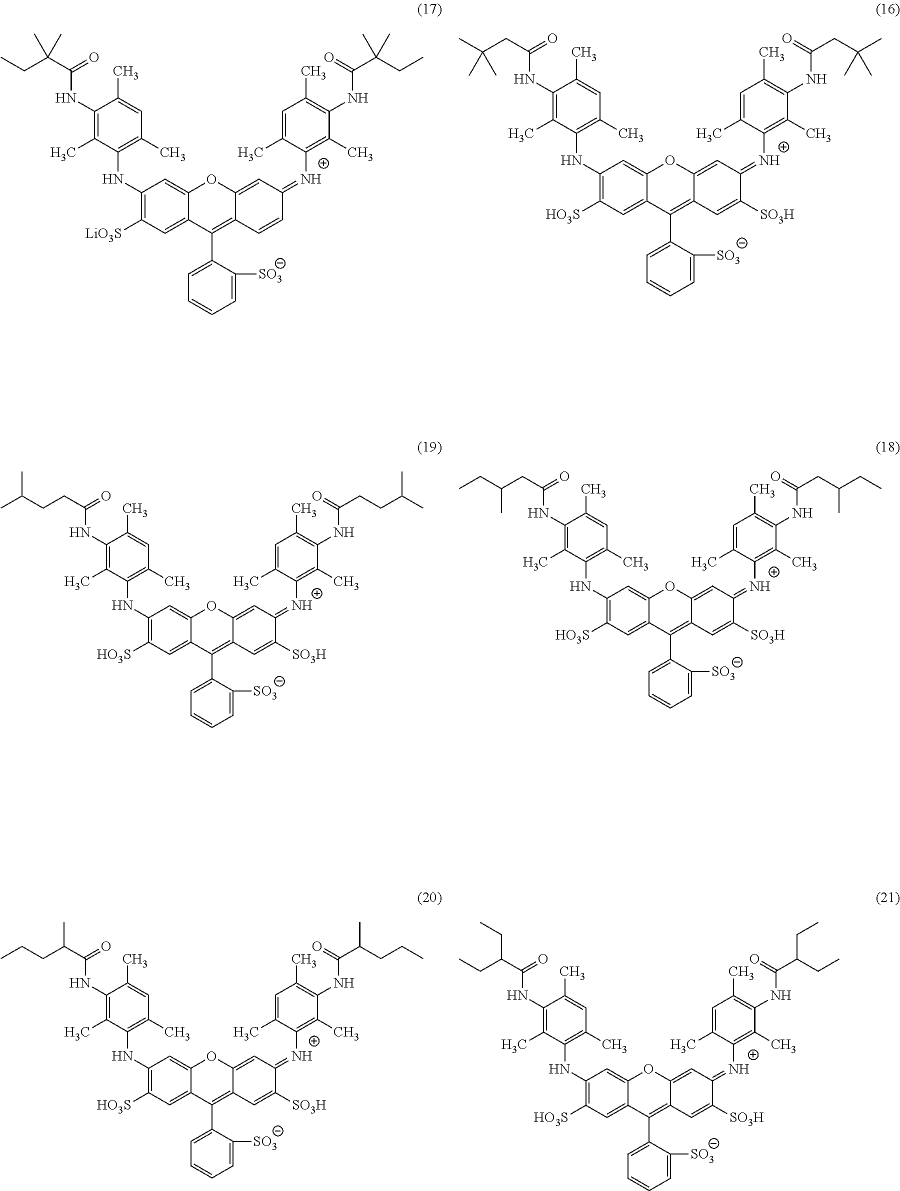

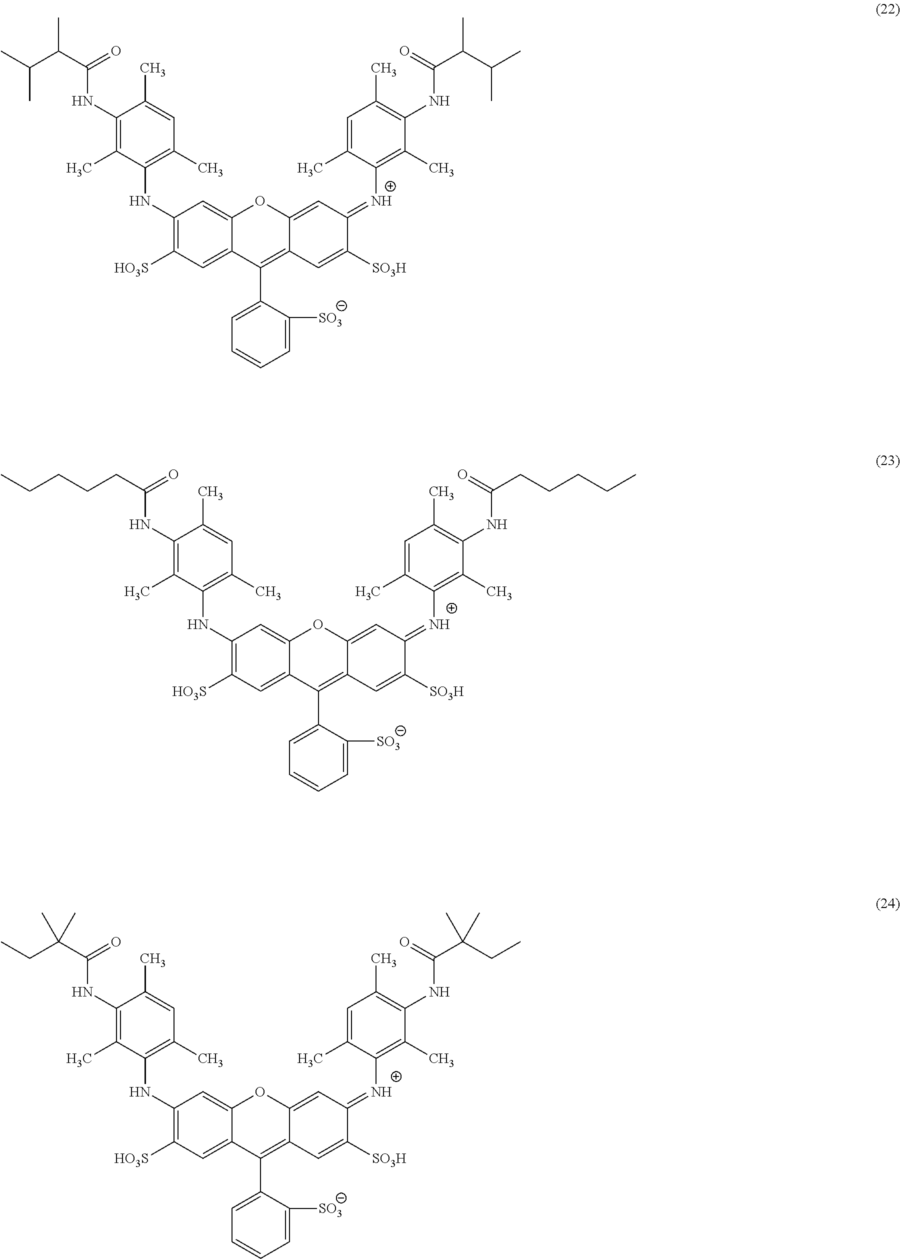

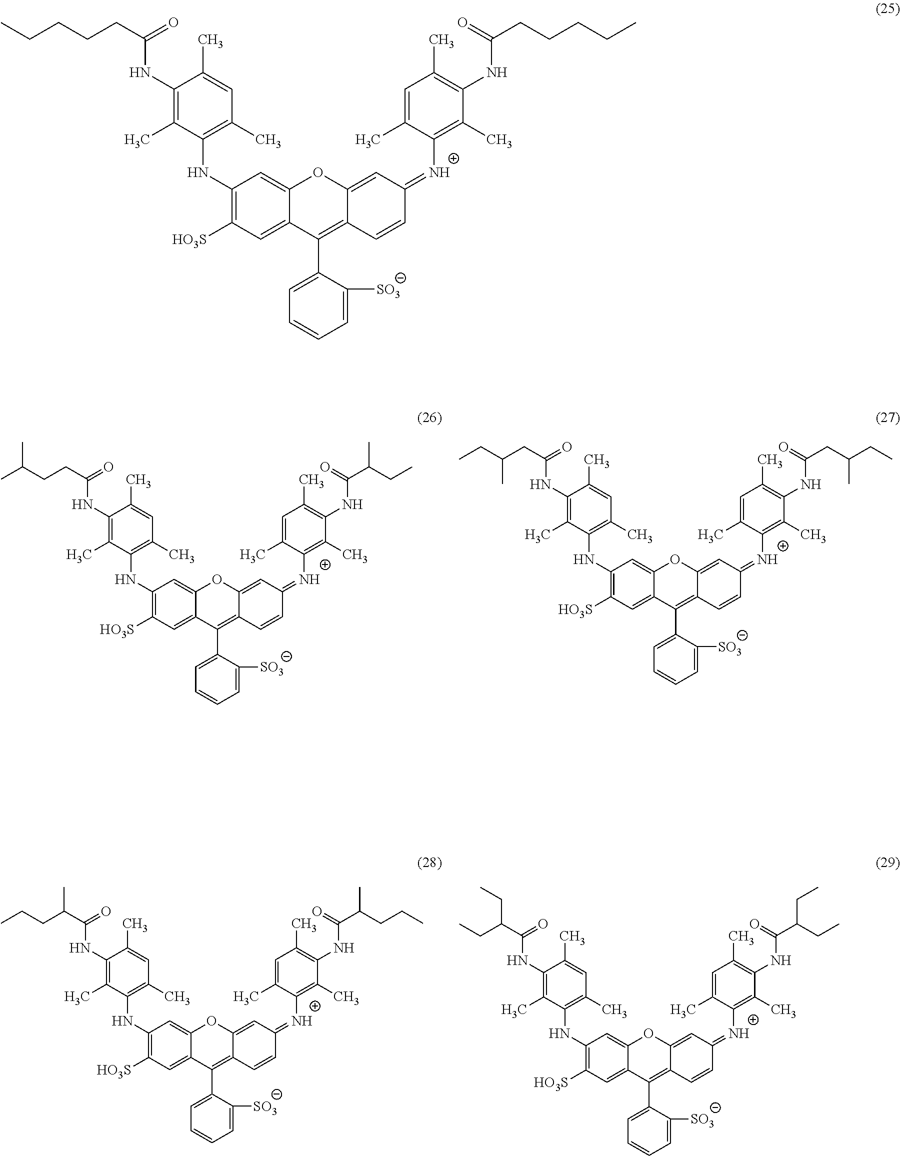

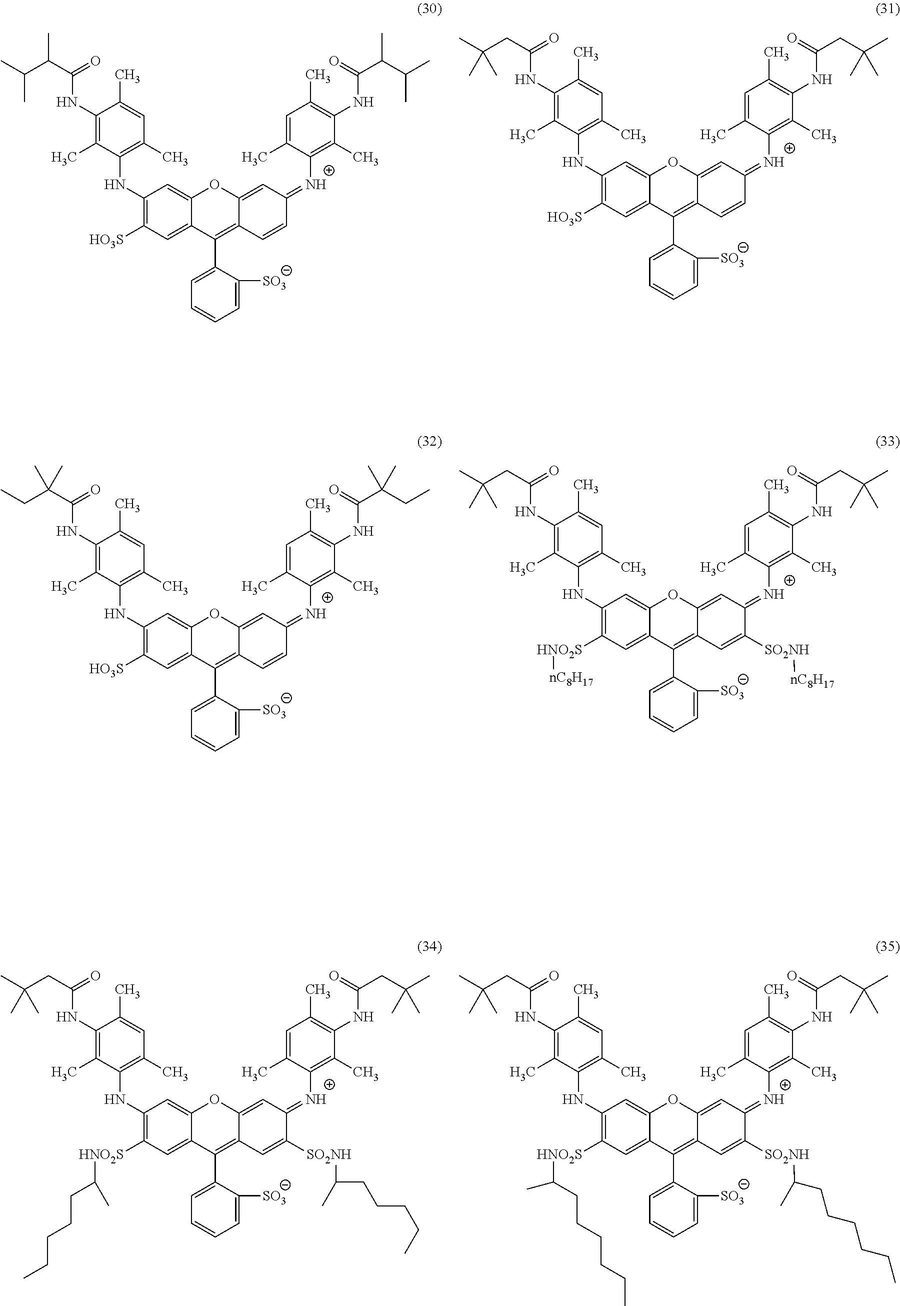

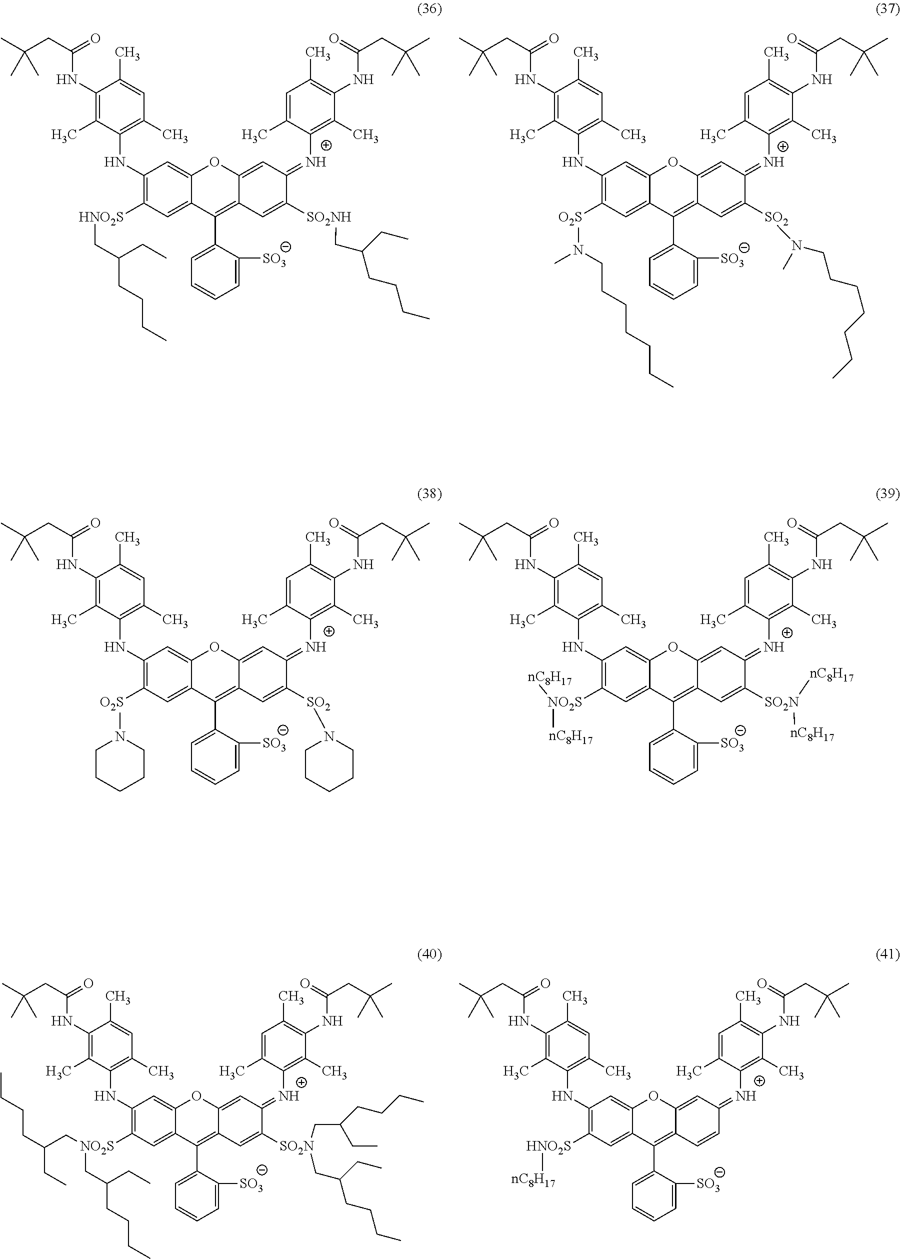

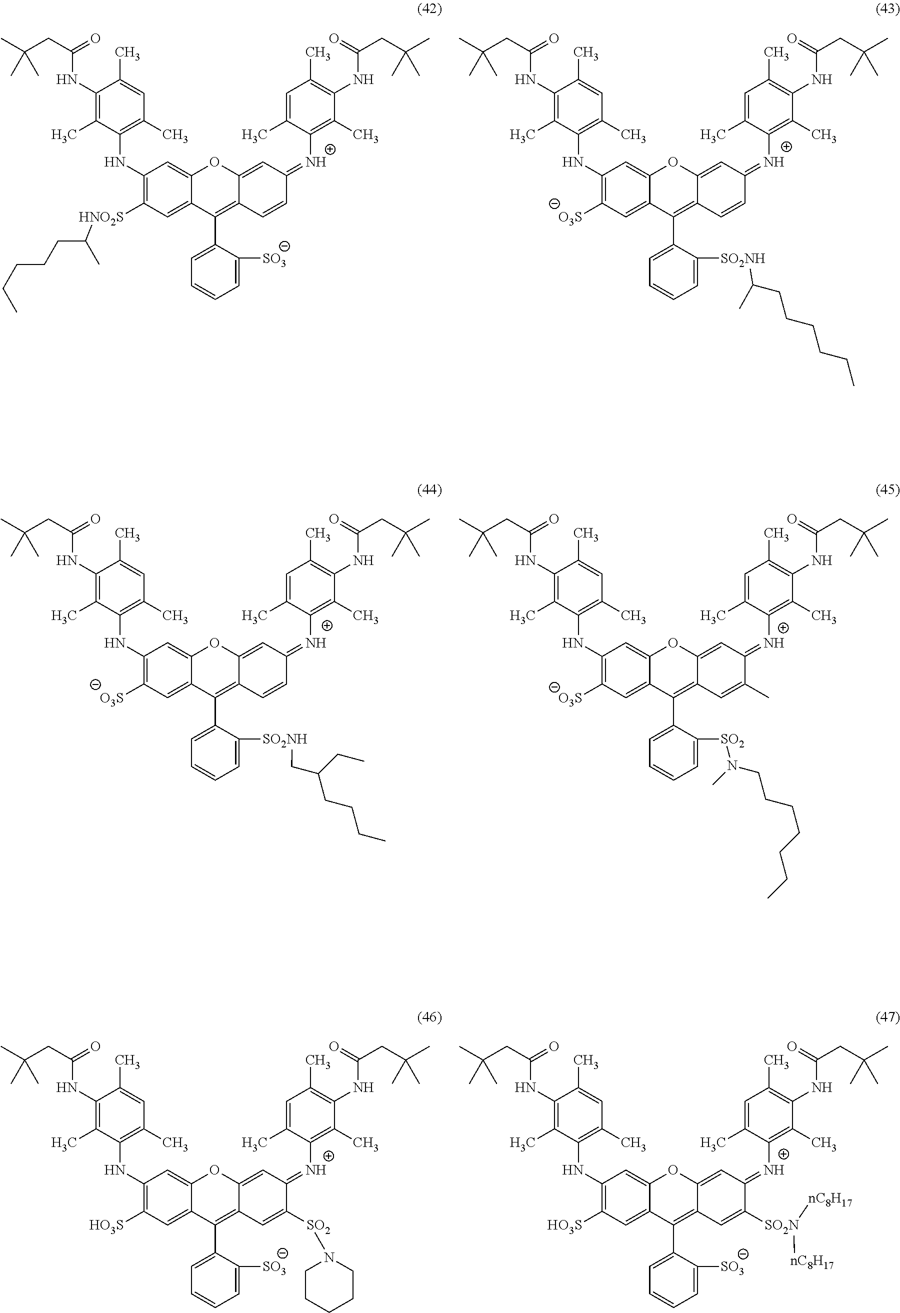

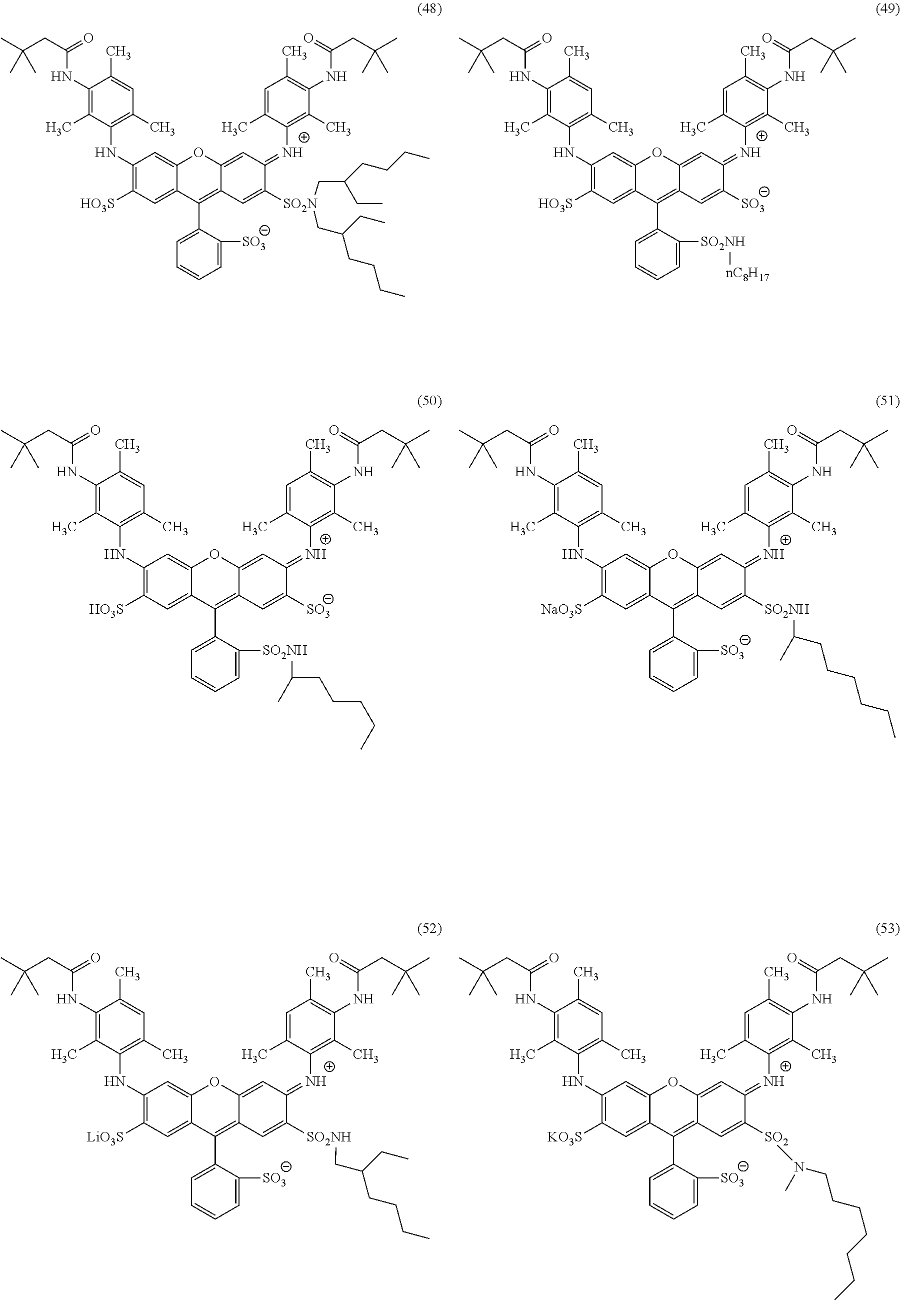

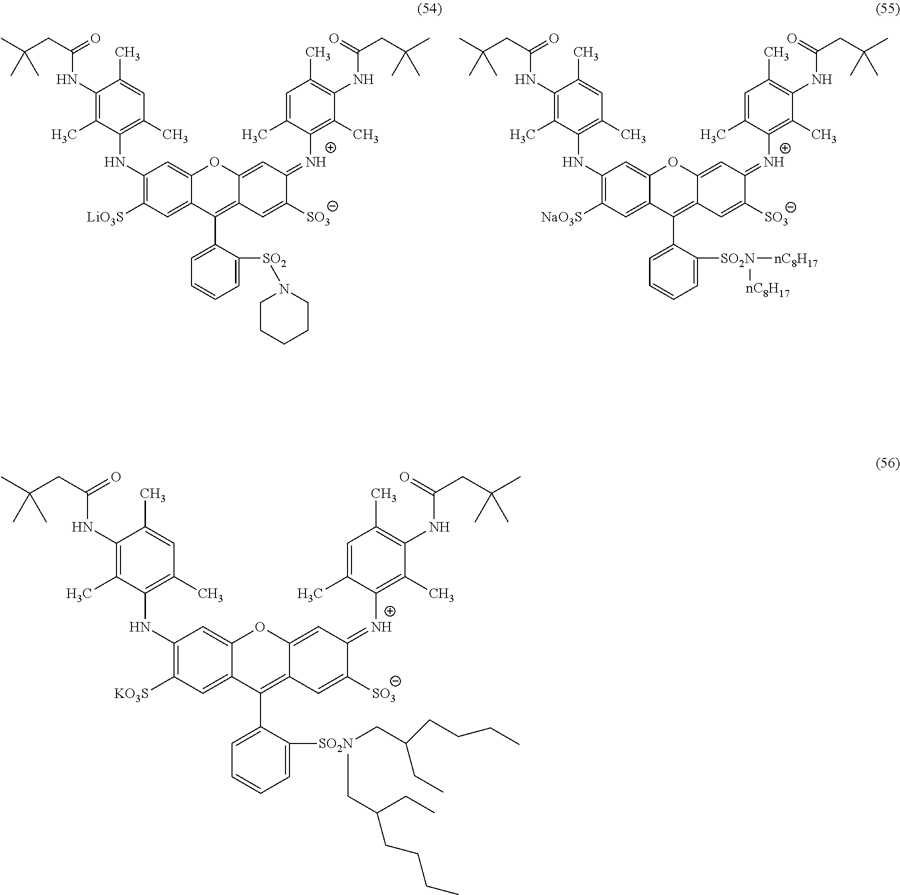

Among those, the compounds (1), (2), (3), (5), (7), (8), (9), (10), (11), (15), (17), (31), (33), (36), (38), (41), (44), (46) and (49) are preferred, and, in particular, the compounds (1), (7), (9), (15), (17), (31), (33), (38), (41), (44) and (46) are more preferred due to having high color developability and excellent heat resistance.

The compounds represented by the general formula (1) may be used singly or in combinations of two or more for adjustment of color tone depending on applications. Furthermore, the compound may be used in combination with a known pigment or dye. Two or more known pigments or dyes may be used in combination.

The pigments for use are not particularly limited and examples thereof include C.I. Pigment Red 48, C.I. Pigment Red 49, C.I. Pigment Red 52, C.I. Pigment Red 58, C.I. Pigment Red 63, C.I. Pigment Red 81, C.I. Pigment Red 122, C.I. Pigment Red 155, C.I. Pigment Red 166, C.I. Pigment Red 169, C.I. Pigment Red 176, C.I. Pigment Red 177, C.I. Pigment Red 209, C.I. Pigment Red 224, C.I. Pigment Red 242, C.I. Pigment Red 254, C.I. Pigment Red 255, C.I. Pigment Red 264, C.I. Pigment Violet 19, C.I. Pigment Violet 23, C.I. Pigment Violet 27 and C.I. Pigment Violet 39.

<Resist Composition for Color Filter>

A resist composition for a color filter with use of the compound represented the general formula (1) is described as follows.

Due to having high color developability and excellent heat resistance, the compound represented by the general formula (1) can be suitably used as a resist composition for a color filter. Also, with use of the resist composition, a color filter having high color developability and excellent heat resistance can be obtained.

The resist composition for a color filter contains a binder resin, a medium, and the compound of the present invention as a colorant. An aspect of the method for manufacturing the resist composition for a color filter is described, though the present invention is not limited thereto. For example, a compound represented by the general formula (1) and a binder resin are added to a solvent while being stirred. On this occasion, a polymerizable monomer, a polymerization initiator, a photoacid generator, and the like may be added thereto on an as needed basis. The material is then stably dissolved or finely dispersed in a medium with a mechanical shearing force applied from a disperser, so that the resist composition for a color filter of the present invention can be obtained.

[Binder Resin]

The binder resin for use in the resist composition is not particularly limited, and examples thereof include one that allows either one of the photoirradiated part and the light-shielding part in exposure for forming picture elements to be dissolved in an organic solvent, an alkaline aqueous solution, water or a commercially available developer. In particular, from the viewpoints of workability and processability after manufacturing of the resist, a binder resin having a composition that allows development in water or an alkaline aqueous solution can be employed.

The binder resin is not particularly limited, and examples of the resin for use include one obtained by copolymerization of a hydrophilic polymerizable monomer having acrylic acid, methacrylic acid, N-(2-hydroxyethyl)acrylamide, N-vinylpyrrolidone or an ammonium salt and a lipophilic polymerizable monomer such as an acrylate, a methacrylate, vinyl acetate, styrene, and N-vinylcarbazole at a proper mixing ratio using a known method.

The binder resin may be used in combination with a radical-polymerizable monomer having an ethylenic unsaturated group, a cationic polymerizable monomer having an oxirane ring or an oxetane ring, a radical generator, an acid generator and a base generator.

The binder resin of this type can be used as a negative-type resist composition. In other words, the solubility of the material is reduced at the exposed part by exposure, so that the light-shielding part is removed by developing.

A combination of a resin having a group that is cleaved by an acid and an acid generator that generates an acid by exposure may be also used. Examples include a resin having a quinone diazide group, a polyhydroxystyrene tert-butyl carbonate ester, and a tetra-hydropyranyl ether.

The binder resin of this type can be used as a positive-type resist composition. In other words, the solubility of the material is improved at the exposed part by exposure, so that the exposed part is removed by developing.

For the negative-type resist composition, a polymerizable monomer to be addition polymerized by exposure (hereinafter also referred to as “photopolymerizable monomer”) can be used. The photopolymerizable monomer is not particularly limited, and can be, for example, a compound having at least one addition polymerizable ethylenic unsaturated double bond in a molecule, with a boiling point of 100° C. or higher at normal pressure.

Specific examples include: monofunctional acrylates and monofunctional methacrylates such as polyethylene glycol monoacrylate, polyethylene glycol monomethacrylate, polypropylene glycol monoacrylate, polypropylene glycol monomethacrylate, phenoxyethyl acrylate, and phenoxyethyl methacrylate; polyfunctional acrylates and polyfunctional methacrylates such as polyethylene glycol diacrylate, polyethylene glycol dimethacrylate, polypropylene glycol diacrylate, polypropylene glycol dimethacrylate, trimethylolethane triacrylate, trimethylolethane trimethacrylate, trimethylolpropane triacrylate, trimethylolpropane trimethacrylate, trimethylolpropane diacrylate, trimethylolpropane dimethacrylate, neopentylglycol diacrylate, neopentylglycol dimethacrylate, pentaerythritol tetraacrylate, pentaerythritol tetramethacrylate, pentaerythritol triacrylate, pentaerythritol trimethacrylate, dipentaerythritol hexaacrylate, dipentaerythritol hexamethacrylate, dipentaerythritol pentaacrylate, dipentaerythritol pentamethacrylate, hexanediol diacrylate, hexanediol dimethacrylate, trimethylolpropane tri(acryloyloxy propyl)ether, tri(acryloyloxy ethyl)isocyanurate, tri(acryloyloxy ethyl)cyanurate, glycerol triacrylate, and glycerol trimethacrylate; and polyfunctional acrylates and polyfunctional methacrylates that can be obtained by adding ethylene oxide or propylene oxide to a polyfunctional alcohol such as trimethylol propane and glycerol, and then acrylating or methacrylating the reaction product. Furthermore, urethane acrylates, polyester acrylates, polyfunctional epoxyacrylates or epoxymethacrylates as reaction products of an epoxy resin and acrylic acid or methacrylic acid can be also used.

Among the photopolymerizable monomers, trimethylolpropane triacrylate, trimethylolpropane trimethacrylate, pentaerythritol tetraacrylate, pentaerythritol tetramethacrylate, dipentaerythritol hexaacrylate, dipentaerythritol hexamethacrylate, dipentaerythritol pentaacrylate, and dipentaerythritol pentamethacrylate are preferably used. The photopolymerizable monomers may be used singly or in combinations of two or more on an as needed basis.

The content of the photopolymerizable monomer is preferably 5 to 50 mass %, more preferably 10 to 40 mass %, relative to the mass of the resist composition (total solid content) of the present invention. With the content being 5 to 50 mass %, the sensitivity to exposure and the strength of photographic paper can be further enhanced, and good adhesion of the resist composition can be obtained.

To a resist composition of the negative type, a photopolymerization initiator may be added. The photopolymerization initiator is not particularly limited, and examples thereof include a vicinal polyketoaldonyl compound, an α-carbonyl compound, an acyloin ether, various quinone compounds, a combination of triallyl imidazole dimer and p-amino phenyl ketone, and a trioxadiazole compound. In particular, 2-benzyl-2-dimethylamino-1-(4-morpholinophenyl)butanone (trade name: IRGACURE 369 manufactured by BASF Corporation) can be used. Yet, in forming picture elements from the resist composition of the present invention by using electron beam irradiation, the photopolymerization initiator is not necessarily required.

To a resist composition of the positive type, a photoacid generator may be added thereto on an as needed basis. The photoacid generator for use is not particularly limited, and examples thereof include known photoacid generators such as salts of an onium ion, i.e., a sulfonium ion, an iodonium ion, a selenium ion, an ammonium ion, or a phosphonium ion, and an anion.

The sulfonium ion is not particularly limited, and examples thereof include triphenylsulfonium, tri-p-trisulfonium, tri-o-trisulfonium, tris(4-methoxyphenyl)sulfonium, 1-naphthyl diphenylsulfonium, diphenyl phenacylsulfonium, phenylmethyl benzylsulfonium, 4-hydroxyphenylmethyl benzylsulfonium, dimethyl phenacylsulfonium, and phenacyl tetrahydrothiophenium.

Examples of the iodonium ion include diphenyliodonium, di-p-tolyliodonium, bis(4-dodecylphenyl)iodonium, bis(4-methoxyphenyl)iodonium, and (4-octyloxyphenyl)phenyliodonium.

The selenium ion is not particularly limited, and examples thereof include a triarylselenium such as triphenylselenium, tri-p-tolylselenium, tri-o-tolylselenium, tris(4-methoxyphenyl)selenium, 1-naphthyldiphenylselenium, tris(4-fluorophenyl)selenium, tri-l-naphthylselenium, and tri-2-naphthylselenium.

Examples of the ammonium ion include a tetraalkylammonium such as tetramethylammonium, ethyltrimethylammonium, diethyldimethylammonium, triethylmethylammonium, tetraethylammonium, trimethyl-n-propylammonium, trimethylisopropylammonium, trimethyl-n-butylammonium, and trimethylisobutylammonium.

The phosphonium ion is not particularly limited, and examples thereof include tetraphenylphosphonium, tetra-p-tolylphosphonium, tetrakis(2-methoxyphenyl)phosphonium, triphenylbenzylphosphonium, triphenylphenacylphosphonium, triphenylmethylphosphonium, triethylbenzylphosphonium, and tetraethylphosphonium.

The anion is not particularly limited, and examples thereof include: a perhalogenate ion such as ClO₄⁻ and BrO₄⁻; a halogenated sulfonate ion such as FSO₃⁻ and ClSO₃⁻, a sulfate ion such as CH₃SO₄⁻, CF₃SO₄⁻ and HSO₄⁻; a carbonate ion such as HCO₃⁻ and CH₃CO₃⁻; an aluminate ion such as AlCl₄⁻ and AlF₄⁻; a hexafluorobismuthate ion, a carboxylate ion such as CH₃COO⁻, CF₃COO^{'1}, C₆H₅COO⁻, CH₃C₆H₄COO⁻, C₆F₅COO⁻ and CF₃C₆H₄COO⁻; an arylborate ion such as B (C₆H₅)₄⁻ and CH₃CH₂CH₂CH₂B(C₆H₅)₃⁻; a thiocyanate ion, and a nitrate ion, though not limited thereto.

[Medium]

In the resist composition, water or an organic solvent may be used as the medium for dissolving or dispersing a compound represented by the general formula (1), a binder resin, and a photopolymerizable monomer, a photopolymerization initiator and a photoacid generator that are added on an as needed basis.

The organic solvent is not particularly limited, and examples thereof include cyclohexanone, ethyl cellosolve acetate, butyl cellosolve acetate, 1-methoxy-2-propyl acetate, diethylene glycol dimethyl ether, ethylbenzene, 1,2,4-trichlorobenzene, ethylene glycol diethyl ether, xylene, ethyl cellosolve, methyl-n-amyl ketone, propylene glycol monomethyl ether, toluene, methyl ethyl ketone, ethyl acetate, methanol, ethanol, isopropanol, butanol, methyl isobutyl ketone, and a petroleum solvent. In particular, propylene glycol monomethyl ether is suitably used.

The organic solvents may be used singly or in combinations of two or more.

[Colorant]

As the colorant to constitute the resist composition, the compound represented by the general formula (1) is used. The compounds may be used singly or in combinations of two or more. In order to obtain desired spectral characteristics, other known dyes and/or pigments may be used in combination for color matching. The dyes that can be used together is not particularly limited, and examples include a condensed azo compound, an azo-metal complex, a diketo pyrrolopyrrole compound, an anthraquinone compound, a quinacridone compound, a naphthol compound, a benzimidazolone compound, a thioindigo compound, a perylene compound, a methine compound, an allylamide compound, and a basic dye lake compound. The pigment that can be used together is not particularly limited, and examples thereof include: C.I. Pigment Red 48, 49, 52, 58, 63, 81, 122, 155, 166, 169, 176, 177, 209, 224, 242, 254, 255 and 264; and C.I. Pigment Violet 19, 23, 27 and 39.

The content of the dyes and/or pigments in the resist composition for a color filter is not particularly limited as long as the total of the content of the compound represented by the formula (1) as the essential component of the resin composition of the present invention and the content of the dyes and/or pigments as the optional components is in the range of typically 0.01 to 70 parts by mass, preferably 0.5 to 50 parts by mass, more preferably 1.0 to 40 parts by mass, relative to 100 parts by mass of the total solid content of the resist composition.

To the resist composition for a color filter, an ultraviolet absorber and a silane coupling agent for enhancing the adhesion to a glass substrate in manufacturing a filter may be added on an as needed basis other than the additives described above.

The disperser for use in dissolving or finely dispersing the resist composition for a color filter is not particularly limited, and examples thereof include a shear rotary homogenizer, a medium-type disperser such as a ball mill, a sand mill and an attritor, and a high-pressure opposing collision-type disperser.

As described above, the resist composition for a color filter achieves the high color developability and excellent heat resistance due to containing the compound represented by the general formula (1).

<Color Filter>

The color filter with use of the compound represented by the general formula (1) is described as follows.

In a color filter having two or more picture elements with different spectral characteristics that are adjacently disposed, the resist composition of the present invention is used in picture elements to constitute at least one color of a plurality of picture element colors (e.g., red, green and blue), so that the color filter having high color developability and excellent heat resistance can be obtained.

The method for forming each of the color picture elements is not particularly limited, and examples thereof include ink jetting, printing and photolithography.

In use of ink jetting, a black matrix is formed on a glass substrate and the resist composition for a color filter is emitted as an ink to the opening of the black matrix by using an ink jet apparatus for coloring. The resist composition is then heat-treated to form a color layer.

To the black matrix, a water repellent agent such as silicon and fluorine may be added.

In use of printing, the resist composition for a color filter is applied and dried for the formation.

In use of photolithography, a resist composition is applied to a transparent substrate such that the dried film has a thickness of 0.1 to 20 μm, preferably 0.5 to 5 μm, and dried for the formation.

Examples of the application method include bar coating, spin coating, spray coating, roll coating and slit coating.

On an as needed basis, the dried film is exposed to ultraviolet rays through a photo mask for the exposure. The film is then immersed in a solvent or an alkaline developer, so that uncured parts are removed for the formation.

Alternatively, the color filter may be manufactured by electrodeposition, transferring, etc.

The color filter can be suitably used for liquid crystal display apparatuses, organic EL displays, organic EL devices, solid imaging devices (CCD and CMOS), etc.

The display apparatuses may be ones that display fixed information or ones that display variable information such as tachometers and speed meters.

The liquid display apparatus is not particularly limited, and can have a structure including, for example, a backlight, a polarized film, a display electrode, an orientation film, a common electrode, and a color filter of the present invention, and a polarized film laminated in sequence.

The organic EL display is not particularly limited, and can have a color filter of the present invention on any one of the upper and lower sides of the multi-layer organic light emitting device.

The solid imaging device is not particularly limited, and can have a structure including, for example, a color filter of the present invention and a micro lens laminated on a silicon wafer having a transfer electrode and a photodiode.

<Polyamide-Containing Dyed Fiber>

A dyed product with use of the compound represented by the general formula (1) is described as follows.

The polyamide-containing dyed fiber of the present invention is a thread or fabric that contains polyamide fibers dyed with the compound represented by the general formula (1). The polyamide-containing fiber is not particularly limited, and in particular, silk is preferred.

In the dye industry, dyeing by immersing threads or fabrics in a bath in which a dye is dissolved or dispersed (dip dyeing) is referred to as dyeing, and a method for forming a printed pattern by imparting a dye to a part of a fabric and putting another color dye on the other part is referred to as printing, in some cases. The product dyed by any one of the methods is included in the dyed product of the present invention.

In dyeing, the compound represented by the general formula (1) can be contacted with a polyamide-containing fiber by any method, which may be an appropriate conventional method in the technical field. Examples of the dip dyeing include winch dyeing and jigger dyeing, and examples of the printing include screen printing, roller printing, ink jetting and electrophotography.

### EXAMPLES

With reference to Examples and Comparative Examples, the present invention is further described in detail as follows, though the present invention is not limited to the Examples. In the description, “parts” and represent “parts by mass” and “mass %”, respectively, unless otherwise noted. The obtained compounds were identified using a ¹H nuclear magnetic resonance spectroscopic (¹H-NMR) apparatus (ECA-400, manufactured by JEOL Ltd.) and an LC/TOF MS apparatus (LC/MSD TOF, manufactured by Agilent Technologies).

### Example 1

<Manufacturing of Compound (1)>

Under nitrogen atmosphere, N-(3-amino-2,4,6-trimethylphenyl)-3,3-dimethylbutanamide (38 g, 0.153 mol) was added to an N-methyl-pyrrolidone solution (100 mL) of raw material A (15 g, 0.037 mol) having the following structure to cause a reaction at 150° C. for 6 hours. After completion of the reaction, the product was cooled to room temperature, to which 100 mL of 2 mol/L of hydrochloric acid was slowly added and stirred for 30 minutes. After filtration, the product was washed with 100 mL of water, and the obtained solid was dried. The dried solid was added to 30 g of fuming sulfuric acid ice-cooled at 5° C. or lower, and stirred at 30 to 32° C. for 24 hours. After completion of the reaction, the reaction liquid was slowly added onto 200 g of ice and stirred. After filtration, the product was washed with cold water, and the solid was suspended in 50 mL of water. A sodium hydroxide aqueous solution was used to adjust the pH at 7 to 8, and then acetone was used for crystallization to obtain 17.1 g of the compound (1). The maximum absorption wavelength was 534 nm (H₂O).

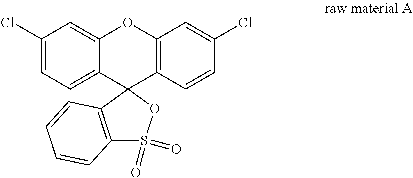 [SMILES: O=S1(=O)OC2(c3ccc(Cl)cc3Oc3cc(Cl)ccc32)c2ccccc21]

### Examples 2 to 10, and Comparative Examples 1 to 5

Each of the compounds and comparative compounds described in Table 1 was obtained by manufacturing in the same manner as in Example 1, except that N-(3-amino-2,4,6-trimethylphenyl)-2,2-dimethylpropanamide in Example 1 was replaced with an amide corresponding to the structure of the intended compound.

### Example 11

To 5 mL of methanol solution of 15 g of the compound (1), 30 mL of concentrated hydrochloric acid was added and stirred for 1 hour to precipitate a solid, which was then filtered and washed with 500 mL of water to obtain 10.5 g of a compound (17).

### Example 12

By the same procedure as in Example 11 except that a compound (15) was used instead of the compound (1) in Example 11, 11.2 g of a compound (31) was obtained.

### Example 13

A solution of a compound (17) (5 g, 5 parts) in 50 ml of tetrahydrofuran and 2.5 parts of N,N-dimethylformaldehyde was ice-cooled, to which 11 parts of thionyl chloride was slowly dropped to maintain the temperature at 10° C. or lower. After the reaction at room temperature for 2 hours, the reaction system was ice-cooled again, and 10 parts of n-octylamine was dropped thereto to cause a reaction at room temperature for 5 hours. After completion of the reaction, the reaction system was concentrated under reduced pressure by an evaporator, and to which 50 mL of methanol was added. The methanol solution was added to 50 parts of 25% acetic acid aqueous solution, and the precipitated solid was filtered. The obtained solid was refined by column chromatography to obtain a compound (33) (2.1 g).

### Examples 14 to 21

By the same procedure as in Example 13, except that the amount of thionyl chloride (5.05 parts, in the case of one amide) was changed, and octylamine was replaced with an amine corresponding to the structure of the intended compound, with the amount changed, compounds (34), (35), (36), (37), (38), (41), (44) and (46) were obtained.

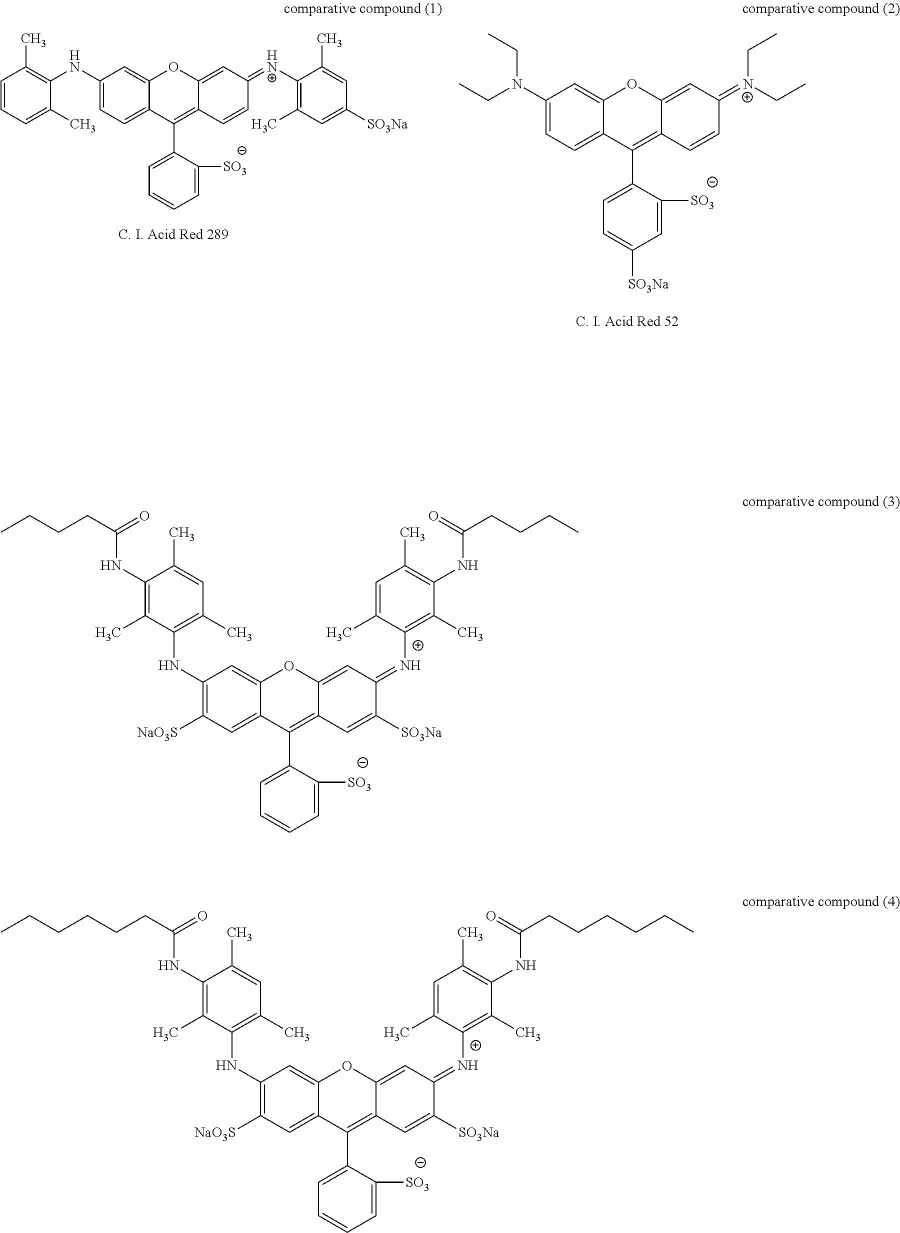

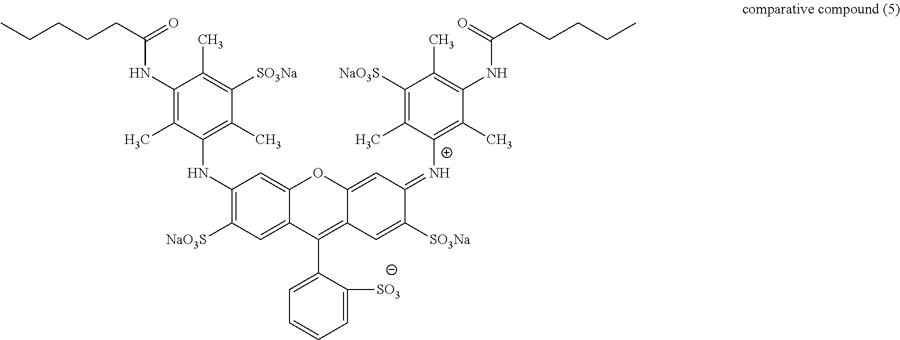

[Evaluation on Heat Resistance]

The heat resistance of each of the compounds and comparative compounds was evaluated by using a simultaneous thermal gravity/differential thermal analyzer (TG-DTA) (trade name: STA7200RV, manufactured by Hitachi High-Tech Science Corporation). In the evaluation on the heat resistance, 5 mg of a sample was heated from a temperature of 45° C. to 550° C. at a temperature elevation rate of 10° C./min. FIGURE is a graph illustrating the specific weight decrease of the compound (1) manufactured in Example 1 in the thermal gravity/differential thermal analysis (TG-DTA).

The results are shown in Table 1.

The evaluation criteria are as follows.

A: The weight decrease at 450° C. is less than 20%.

B: The weight decrease at 450° C. is 20% or more and less than 50%.

C: The weight decrease at 450° C. is 50% or more.

TABLE 1

| | | Maximum absorption | Evaluation |
|---|---|---|---|
| | | wavelength | on heat |
| | Compound | (nm) | resistance |
| Example 1 | Compound (1) | 534 | A |
| Example 2 | Compound (2) | 533 | A |
| Example 3 | Compound (3) | 533 | A |
| Example 4 | Compound (5) | 532 | B |
| Example 5 | Compound (7) | 533 | A |
| Example 6 | Compound (8) | 533 | B |
| Example 7 | Compound (9) | 528 | A |
| Example 8 | Compound (10) | 528 | A |
| Example 9 | Compound (11) | 526 | A |
| Example 10 | Compound (15) | 528 | A |
| Example 11 | Compound (17) | 528 | A |
| Example 12 | Compound (31) | 528 | A |
| Example 13 | Compound (33) | 528 | A |
| Example 14 | Compound (34) | 528 | A |
| Example 15 | Compound (35) | 528 | A |
| Example 16 | Compound (36) | 528 | A |
| Example 17 | Compound (37) | 528 | A |
| Example 18 | Compound (38) | 528 | A |
| Example 19 | Compound (41) | 527 | B |
| Example 20 | Compound (44) | 528 | B |
| Example 21 | Compound (46) | 528 | A |
| Comparative | Comparative | 527 | C |
| Example 1 | compound (1) | | |
| Comparative | Comparative | 566 | C |
| Example 2 | compound (2) | | |
| Comparative | Comparative | 532 | C |
| Example 3 | compound (3) | | |
| Comparative | Comparative | 534 | C |
| Example 4 | compound (4) | | |
| Comparative | Comparative | 530 | C |
| Example 5 | compound (5) | | |

<Manufacturing of Resist Composition for Color Filter and Color Filter>

A resist composition for a color filter and a color filter were manufactured by the following methods.

### Example 22

Into 12 parts of the compound (1) synthesized in Example 1, 120 parts of cyclohexanone was mixed and dispersed for 1 hour using an attritor (manufactured by Mitsui Mining Co., Ltd.), so that an ink (1) for resist composition was obtained.

Subsequently, to 96 parts of a cyclohexanone solution of 6.7 parts of acrylic copolymer composition (weight average molecular weight Mw: 10,000) with a monomer ratio of 40 mass % of n-butylmethacrylate, 30 mass % of acrylic acid, and 30 mass % of hydroxyethylmethacrylate, 1.3 parts of dipentaerythritol pentaacrylate, and 0.4 parts of 2-benzyl-2-dimethylamino-1-(4-morpholinophenyl)-butanone (photopolymerization initiator), 22 parts of the ink (1) for resist composition was slowly added and stirred at room temperature for 3 hours. The reaction product was filtered with a 1.5-μm filter, so that the resist composition (1) for a color filter was obtained.

The resist composition (1) for a color filter applied to a glass substrate by spin coating was dried at 90° C. for 3 minutes, and then subjected to whole surface exposure and post curing at 180° C., so that the color filter (1) was manufactured.

### Examples 23 to 42

Resist compositions (2) to (21) for a color filter were obtained in the same manner as in Example 22, except that the compound (1) in Example 22 was changed to each of the compounds shown in Table 2. Color filters (2) to (21) were also manufactured by the same procedure as in Example 22, except that each of the obtained resist compositions (2) to (21) for a color filter was used instead of the resist composition (1) for a color filter.

### Comparative Examples 6 to 10

Resist compositions (1) to (5) for comparative color filters were obtained in the same manner as in Example 22, except that the compound (1) in Example 22 was changed to each of comparative compounds (1) to (5). Comparative color filters (1) to (5) were also manufactured by the same procedure as in Example 22, except that the obtained resin compositions (1) to (5) for comparative color filters were used instead of the resist composition (1) for a color filter.

Evaluation on Heat Resistance

Each of the obtained color filters and comparative color filters were heat-treated at 230° C. for 180 minutes and the spectral transmittance before and after the treatment was measured. Using a reflection densitometer SpectroLino (trade name, manufactured by Gretag Macbeth Inc.), the color difference between before and after the heat treatment (ΔE) was calculated based on the following expression in the CIE 1976 L*a*b* color space (CIELAB color space) for the evaluation on heat resistance. The results are shown in Table 2.

ΔE=\sqrt{(L₂*−L₁*)²+(a₂*−a₁*)²+(b₂*−b₁*)²}

In the expression, the chromaticity values before the heat treatment were a₁*, b₁* and L₁*, and the chromaticity values after the heat treatment were a₂*, b₂* and L₂*.

The evaluation criteria are as follows.

A: ΔE is less than 3.0.

B: ΔE is 3.0 or more and less than 5.0.

C: ΔE is 5.0 or more.

TABLE 2

| | | | | Evaluation |
|---|---|---|---|---|
| | | | | on heat |
| | Compound | Name | ΔE | resistance |
| Example 22 | Compound (1) | Color filter (1) | 2.1 | A |
| Example 23 | Compound (2) | Color filter (2) | 2.3 | A |
| Example 24 | Compound (3) | Color filter (3) | 2.5 | A |
| Example 25 | Compound (5) | Color filter (4) | 3.2 | B |
| Example 26 | Compound (7) | Color filter (5) | 2.8 | A |
| Example 27 | Compound (8) | Color filter (6) | 3.6 | B |
| Example 28 | Compound (9) | Color filter (7) | 2.2 | A |
| Example 29 | Compound (10) | Color filter (8) | 2.7 | A |
| Example 30 | Compound (11) | Color filter (9) | 2.2 | A |
| Example 31 | Compound (15) | Color filter (10) | 2.6 | A |
| Example 32 | Compound (17) | Color filter (11) | 2.1 | A |
| Example 33 | Compound (31) | Color filter (12) | 2.2 | A |
| Example 34 | Compound (33) | Color filter (13) | 2.5 | A |
| Example 35 | Compound (34) | Color filter (14) | 2.3 | A |
| Example 36 | Compound (35) | Color filter (15) | 2.2 | A |
| Example 37 | Compound (36) | Color filter (16) | 2.1 | A |
| Example 38 | Compound (37) | Color filter (17) | 2.5 | A |
| Example 39 | Compound (38) | Color filter (18) | 2.8 | A |
| Example 40 | Compound (41) | Color filter (19) | 2.6 | A |
| Example 41 | Compound (44) | Color filter (20) | 2.4 | A |
| Example 42 | Compound (46) | Color filter (21) | 2.5 | A |
| Comparative | Comparative | Comparative color | 5.2 | C |
| Example 6 | compound (1) | filter (1) | | |
| Comparative | Comparative | Comparative color | — | Unevaluable |
| Example 7 | compound (2) | filter (2) | | |
| Comparative | Comparative | Comparative color | 5.6 | C |
| Example 8 | compound (3) | filter (3) | | |
| Comparative | Comparative | Comparative color | 5.7 | C |
| Example 9 | compound (4) | filter (4) | | |
| Comparative | Comparative | Comparative color | — | Unevaluable |
| Example 10 | compound (5) | filter (5) | | |

Regarding the color developability of the compounds of the present invention and the comparative compounds (1) to (5), any of the compounds exhibited high color developability. However, the comparative compound (2), i.e., C.I. Acid Red 52, and the comparative compound (5) were not able to be dissolved in a resist solvent due to too high water solubility, so that no color filter was manufactured.

### Examples 43 to 50

Resist compositions (22) to (29) for a color filter were obtained in the same manner as in Example 22, except that 12 parts of the compound (1) in Example 22 was changed to 12 parts of the compounds and pigments at the ratios shown in Table 3, respectively. Color filters (22) to (29) were also manufactured by the same procedure as in Example 22, except that the obtained resin compositions (22) to (29) for a color filter were used instead of the resist composition (1) for a color filter. In the pigments shown in Table 3, PR represents Pigment Red.

### Comparative Examples 11 to 15

Resist compositions (6) to (10) for comparative color filters were obtained in the same manner as in Example 22, except that 12 parts of the compound (1) in Example 22 was changed to the comparative compounds and pigments shown in Table 2, respectively. Comparative color filters (6) to (10) were also manufactured by the same procedure as in Example 22, except that the obtained resin compositions (6) to (10) for comparative color filters were used instead of the resist composition (1) for a color filter.

[Evaluation on Heat Resistance]

Each of the obtained color filters and comparative color filters were heat-treated at 230° C. for 300 minutes and the spectral transmittance before and after the treatment was measured. Using a reflection densitometer SpectroLino (trade name, manufactured by Gretag Macbeth Inc.), the color difference between before and after the heat treatment (ΔE) was calculated based on the following expression in the CIE 1976 L*a*b* color space (CIELAB color space) for the evaluation on heat resistance. The results are shown in Table 3.

ΔE=\sqrt{(L₂*−L₁*)²+(a₂*−a₁*)²+(b₂*−b₁*)²}

In the expression, the chromaticity values before the heat treatment were a₁*, b₁* and L₁*, and the chromaticity values after the heat treatment were a₂*, b₂* and L₂*.

The evaluation criteria are as follows.

A: ΔE is less than 1.7.

B: ΔE is 1.7 or more and less than 2.0.

C: ΔE is 2.0 or more.

TABLE 3

| | | | | | Evaluation |
|---|---|---|---|---|---|
| | | Mass | | | on heat |
| | Compound/Pigment | ratio | Name | ΔE | resistance |
| Example 43 | Compound (17)/Pigment Blue 15:6 | 2/8 | Color filter (22) | 1.7 | B |
| Example 44 | Compound (31)/Pigment Red 254 | 1/9 | Color filter (23) | 1.5 | A |
| Example 45 | Compound (33)/Pigment Blue 15:6 | 1/9 | Color filter (24) | 1.6 | A |
| Example 46 | Compound (34)/Pigment Blue 15:6 | 1/9 | Color filter (25) | 1.4 | A |
| Example 47 | Compound (35)/Pigment Green 58 | 3/7 | Color filter (26) | 1.7 | B |
| Example 48 | Compound (36)/Pigment Red 254 | 1/9 | Color filter (27) | 1.4 | A |
| Example 49 | Compound (37)/Pigment Red 254 | 1/9 | Color filter (28) | 1.5 | A |
| Example 50 | Compound (38)/Pigment Blue 15:6 | 2/8 | Color filter (29) | 1.9 | B |
| Comparative | Comparative compound (1)/ | 2/8 | Comparative color | 3.6 | C |
| Example 11 | Pigment Blue 15:6 | | filter (6) | | |
| Comparative | Comparative compound (2)/ | 1/9 | Comparative color | 3.5 | C |
| Example 12 | Pigment Red 254 | | filter (7) | | |
| Comparative | Comparative compound (3)/ | 3/7 | Comparative color | 3.5 | C |
| Example 13 | Pigment Green 58 | | filter (8) | | |
| Comparative | Comparative compound (4)/ | 2/8 | Comparative color | 3.4 | C |
| Example 14 | Pigment Blue 15:6 | | filter (9) | | |
| Comparative | Comparative compound (5)/ | 2/8 | Comparative color | 3.2 | C |
| Example 15 | Pigment Blue 15:6 | | filter (10) | | |

As shown in Tables 2 and 3, the color filters manufactured with use of the compound of the present invention is superior in both of the color developability and the heat resistance to the comparative color filters.

### Example 51

The following printing paste was applied to a silk satin (silk: 100%), dried and then subjected to steam treatment with saturated vapor at 105° C. for 30 minutes. The fabric after the steam treatment was washed with water, then with hot water at 60° C. containing 0.1% of a nonionic surfactant (NEW SOAPER BS-50, manufactured by Nissin Kagaku Kenkyusho Co., Ltd.) for 10 minutes, and dried after washing with water to obtain the fabric dyed with the compound (1).

Printing Paste

Sodium alginate: 4 parts

Ammonium sulfate: 3 parts

Compound (1): 2 parts

Water: 91 parts

### Examples 52 and 53, and Comparative Example 16

Instead of the compound (1) in Example 51, the compounds described in Table 4 were used to obtain the fabrics in Examples 52 and 53, and Comparative Examples 16.

[Evaluation on Wet Rubbing Fastness]

Each of the fabric specimens obtained as described above was subjected to the wet rubbing test prescribed in JIS L0849 using a type II (Gakushin type) tester, and evaluated using a staining grey scale. Based on the staining grey scale, the specimens are classified into grades: a first grade (severely stained) to a fifth grade (slightly stained). The evaluation criteria in the present test are as follows.

A: Fourth grade or higher.

B: Third grade.

C: Second grade or lower.

TABLE 4

| | Compound | Wet rubbing test results |
|---|---|---|
| Example 51 | Compound (1) | Third to fourth grade |
| Example 52 | Compound (31) | Fourth grade |
| Example 53 | Compound (33) | Fourth grade |
| Comparative | Comparative | First to second grade |
| Example 11 | compound (1) | |

It was clearly shown from the results that the dyed products with use of the compounds of the present invention are superior in the wet rubbing fastness to the dyed products with use of the comparative compounds.

### INDUSTRIAL APPLICABILITY

The compound of the present invention has high color developability and excellent heat resistance. The compound of the present invention can be suitably used in a resist composition for a color filter, a color filter, a liquid display apparatus, an organic electroluminescence display apparatus, a solid imaging device, an LED device, an LED display, etc. The compound of the present invention also has excellent wet rubbing fastness, so that a dyed polyamide product with high wet rubbing fastness can be obtained.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2017-016181, filed Jan. 31, 2017 which is hereby incorporated by reference herein in its entirety.

What is claimed is:

1. A compound represented by the following general formula (1): 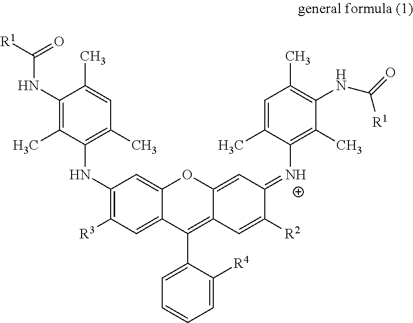
wherein
R¹ each independently represent a straight-chain or branched alkyl group having 5 carbon atoms,
R² represents a hydrogen atom, a sulfo group, a sulfonate group, a sulfonato group, or a sulfonamide group, and
R³ and R⁴ each independently represent a sulfo group, a sulfonate group, a sulfonato group, or a sulfonamide group, wherein
at least one of R² to R⁴ is a sulfonato group.

2. The compound according to claim 1, wherein R², R³ and R⁴ each independently represent a sulfo group, a sulfonato group, or a sulfonamide group.

3. The compound according to claim 2, wherein R² and R³ each independently represent a sulfo group or a sulfonamide group, and R⁴ represents a sulfonato group.

4. A resist composition for a color filter comprising the compound represented by the following general formula (1): 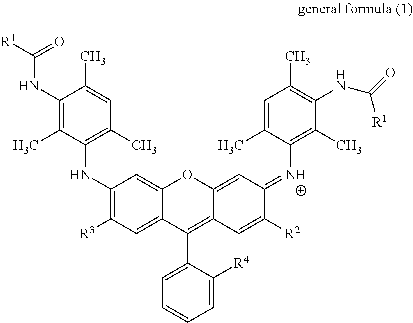
wherein
R¹ each independently represent a straight-chain or branched alkyl group having 5 carbon atoms,
R² represents a hydrogen atom, a sulfo group, a sulfonate group, a sulfonato group, or a sulfonamide group, and
R³ and R⁴ each independently represent a sulfo group, a sulfonate group, a sulfonato group, or a sulfonamide group, wherein
at least one of R² to R⁴ is a sulfonato group.

5. A color filter comprising the compound represented by the following general formula (1): 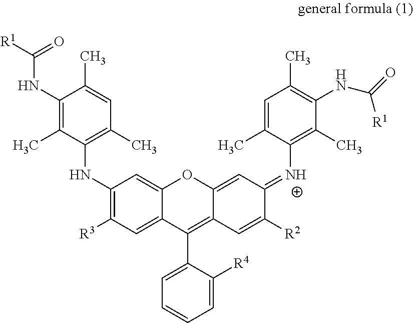
wherein
R¹ each independently represent a straight-chain or branched alkyl group having 5 carbon atoms,
R² represents a hydrogen atom, a sulfo group, a sulfonate group, a sulfonato group, or a sulfonamide group, and
R³ and R⁴ each independently represent a sulfo group, a sulfonate group, a sulfonato group, or a sulfonamide group, wherein
at least one of R² to R⁴ is a sulfonato group.

6. A polyamide-containing dyed fiber dyed with the compound represented by the following general formula (1): 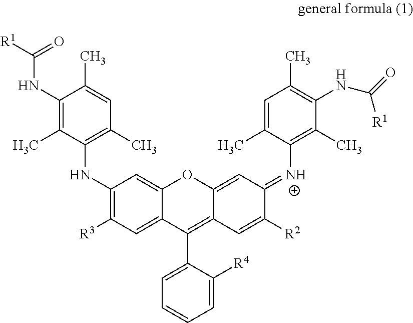
wherein
R¹ each independently represent a straight-chain or branched alkyl group having 5 carbon atoms,
R² represents a hydrogen atom, a sulfo group, a sulfonate group, a sulfonato group, or a sulfonamide group, and
R³ and R⁴ each independently represent a sulfo group, a sulfonate group, a sulfonato group, or a sulfonamide group, wherein
at least one of R² to R⁴ is a sulfonato group.

7. A method for dyeing a polyamide-containing fiber comprising contacting the compound represented by the following general formula (1) with the polyamide-containing fiber. 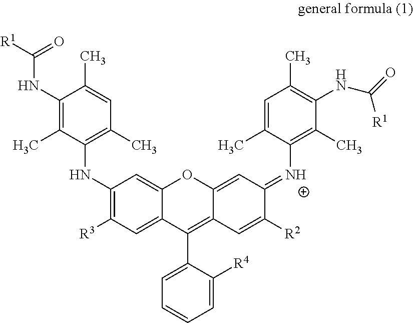
wherein
R¹ each independently represent a straight-chain or branched alkyl group having 5 carbon atoms,
R² represents a hydrogen atom, a sulfo group, a sulfonate group, a sulfonato group, or a sulfonamide group, and
R³ and R⁴ each independently represent a sulfo group, a sulfonate group, a sulfonato group, or a sulfonamide group, wherein
at least one of R² to R⁴ is a sulfonato group.
